(19) United States
(12) Patent Application Publication
(10) Pub. No.: US 2026/0018536 A1
(43) Pub. Date: Jan. 15, 2026

(54) MULTI-LAYER CIRCUIT BOARD HAVING STIMULUS-RESPONSIVE STRAIN LAYER

(71) Applicant: Micron Technology, Inc., Boise, ID (US)

(72) Inventors: Quang NGUYEN, Boise, ID (US); Christopher GLANCEY, Boise, ID (US); Koustav SINHA, Boise, ID (US)

(21) Appl. No.: 19/207,942

(22) Filed: May 14, 2025

Related U.S. Application Data
(60) Provisional application No. 63/670,015, filed on Jul. 11, 2024.

(51) Int. Cl. H01L 23/00; H01L 21/48; H01L 23/15; H01L 23/498; H01L 23/50; H01L 25/16; H10N 30/50

(52) U.S. Cl. CPC H01L 23/562; H01L 21/4846; H01L 23/15; H01L 23/49822; H01L 23/49894; H01L 23/50; H01L 25/16; H10N 30/50

(57) ABSTRACT

Implementations described herein relate to various semiconductor device assemblies. In some implementations, an apparatus includes a dielectric layer having a first material that is an insulative material, a conductive layer having a second material that is a conductive material, and a stimulus-responsive strain layer having a third material that deforms in response to an applied stimulus.

### CROSS-REFERENCE TO RELATED APPLICATION

This patent application claims priority to U.S. Provisional Patent Application No. 63/670,015, filed on Jul. 11, 2024, entitled “MULTI-LAYER CIRCUIT BOARD HAVING STIMULUS-RESPONSIVE STRAIN LAYER,” and assigned to the assignee hereof. The disclosure of the prior Application is considered part of and is incorporated by reference into this patent application.

### TECHNICAL FIELD

The present disclosure generally relates to semiconductor devices and methods of forming semiconductor devices. For example, the present disclosure relates to a multi-layer circuit board having a stimulus-responsive strain layer.

### BACKGROUND

A semiconductor package may include a semiconductor substrate, one or more semiconductor electronic components coupled to and/or embedded in the semiconductor substrate, and a casing formed over the semiconductor substrate to encapsulate the one or more semiconductor electronic components. The one or more semiconductor electronic components may be interconnected by electrical interconnects to form one or more semiconductor devices, such as one or more integrated circuits (ICs) (e.g., one or more dies or chips). For example, the semiconductor electronic components and the electrical interconnects may be fabricated on a semiconductor wafer to form one or more ICs before being diced into dies or chips and then packaged. A semiconductor package may be referred to as a semiconductor chip package that includes one or more ICs. A semiconductor package protects the semiconductor electronic components and the electrical interconnects from damage and includes a mechanism for connecting the semiconductor electronic components and the electrical interconnects to external components (e.g., a circuit substrate), such as via balls, pins, leads, contact pads, or other electrical interconnect structures. A semiconductor device assembly may be or may include a semiconductor package, multiple semiconductor packages, and/or one or more components of a semiconductor package (e.g., one or more semiconductor devices with or without a casing).

An electronic system assembly may include multiple semiconductor packages electrically coupled to a carrier substrate (e.g., circuit substrate). An electronic system assembly may include additional system components electrically coupled to the carrier substrate. The carrier substrate may include electrical interconnects and conductive paths used for interconnecting system components, including the multiple semiconductor packages and other system components of the electronic system assembly. Accordingly, the multiple semiconductor packages may be electrically connected to each other and/or to one or more additional system components via the carrier substrate to form the electronic system assembly. By way of example, other system components may include passive components (e.g., storage capacitors), processing units (e.g., a central processing unit (CPU), a graphics processing unit (GPU), a microprocessor, and/or a microcontroller), control units (e.g., a microcontroller, a memory controller, and/or a power management controller), or one or more other electronic components.

### BRIEF DESCRIPTION OF THE DRAWINGS

FIG. 1 is a diagram of an example apparatus that may be manufactured using techniques described herein.

FIG. 2 is a diagram of an example memory device that may be manufactured using techniques described herein.

FIG. 3 is a flowchart of an example method associated with a multi-layer circuit board including a stimulus-responsive strain layer described herein.

FIG. 4 is a flowchart of an example method of forming an integrated assembly or memory device having a multi-layer circuit board including a stimulus-responsive strain layer described herein.

FIG. 5 is a flowchart of an example method of forming an integrated assembly or memory device having a multi-layer circuit board including a stimulus-responsive strain layer described herein.

FIGS. 6A through 6E are diagrammatic views showing formation of a multi-layer circuit board having a stimulus-responsive strain layer at example process stages of an example process of forming the multi-layer circuit board.

FIGS. 7A through 7C are diagrammatic views showing example operations related to a multi-layer circuit board including a stimulus-responsive strain layer.

### DETAILED DESCRIPTION

The field of electronics assembly manufacturing may involve the design and assembly of electronic components onto a multi-layer circuit board that includes dielectric layers interspersed with conductive layers having electrical traces. Examples of the electronic components include semiconductor packages having DRAM memory integrated circuitry, NAND memory integrated circuitry, logic integrated circuitry, or power management integrated circuitry. The multi-layer circuit board may be a printed circuit board (PCB) used in a memory module application, a PCB used in a server motherboard application, or a ceramic circuit board used in a radio frequency/microwave application, among other examples.

In some cases, thermal expansion mismatches between the electronic components and the substrate at an elevated temperature (e.g., during a solder reflow operation that joins the electronic components and the substrate) may cause a warpage of the substrate, leading to quality and reliability defects (e.g., solder joint reliability defects, open circuits, and/or lifted pads). In other cases, warpage of the substrate at an elevated temperature may reduce a performance of an end-use system that uses the substrate (e.g., a warped substrate of a memory module may intermittently connect with a socket or other connector of the end-use system).

Implementations described herein include devices, systems, and methods related to a multi-layer circuit board including a stimulus-responsive strain layer. The stimulus-responsive strain layer, which may include a piezoelectric material, may be triggered in an environment that causes warpage to the multi-layer circuit board. Triggering the stimulus-responsive strain layer in the environment may introduce a strain that counteracts the warpage and flattens the multi-layer circuit board.

In this way, the stimulus-responsive strain layer may reduce a likelihood of quality and reliability defects in an assembly that includes the multi-layer circuit board. Additionally, the stimulus-responsive strain layer may improve a performance of an end-use system that uses the multi-layer circuit board. By improving the quality and reliability of the assembly, as well as improving the performance of the end-use system, an amount of resources used to support a market consuming a product including the multi-layer circuit board (e.g., raw materials, manufacturing tools, labor, and/or computing resources) is reduced.

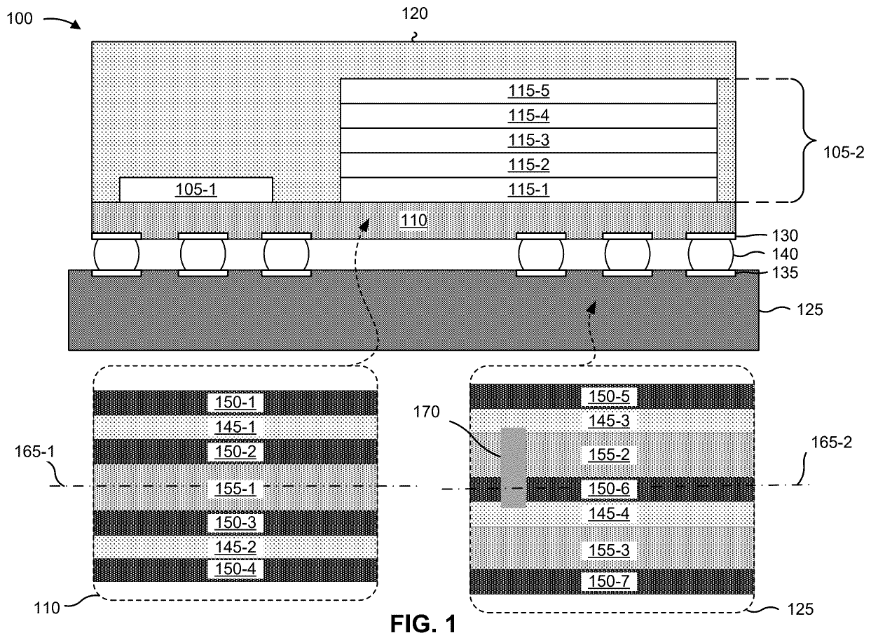

FIG. 1 is a diagram of an example apparatus 100 that may be manufactured using techniques described herein. The apparatus 100 may include any type of device or system that includes one or more integrated circuits 105. For example, the apparatus 100 may include a memory device, a flash memory device, a NAND memory device, a NOR memory device, a random access memory (RAM) device, a read-only memory (ROM) device, a dynamic RAM (DRAM) device, a static RAM (SRAM) device, a solid state drive (SSD), a microchip, and/or a system on a chip (SoC), among other examples. In some cases, the apparatus 100 may be referred to as a semiconductor package, an assembly, a semiconductor device assembly, or an integrated assembly.

As shown in FIG. 1, the apparatus 100 may include one or more integrated circuits 105, shown as a first integrated circuit 105-1 and a second integrated circuit 105-2, disposed on a substrate 110 (e.g., an interposer). An integrated circuit 105 may include any type of circuit, such as an analog circuit, a digital circuit, a radiofrequency (RF) circuit, a power supply, a power management circuit, an input-output (I/O) chip, an application-specific integrated circuit (ASIC), a field-programmable gate array (FPGA), and/or a memory device (e.g., a NAND memory device including NAND memory integrated circuitry, a NOR memory device including NOR integrated circuitry, or a DRAM device including dynamic random access memory integrated circuitry). An integrated circuit 105 may be mounted on or otherwise disposed on a surface of the substrate 110. Although the apparatus 100 is shown as including two integrated circuits 105 as an example, the apparatus 100 may include a different number of integrated circuits 105.

In some implementations, an integrated circuit 105 may include a single semiconductor die 115 (sometimes called a die), as shown by the first integrated circuit 105-1. In some implementations, an integrated circuit 105 may include multiple semiconductor dies 115 (sometimes called dies), as shown by the second integrated circuit 105-2, which is shown as including five semiconductor dies 115-1 through 115-5.

As shown in FIG. 1, for an integrated circuit 105 that includes multiple dies 115, the dies 115 may be stacked on top of each other to reduce a footprint of the apparatus 100. In some implementations, a spacer may be present between dies 115 that are adjacent to one another in the stack to enable electrical separation and heat dissipation. The stacked dies 115 may include three-dimensional electrical interconnects, such as through-silicon vias (TSVs), to route electrical signals between dies 115. Although the integrated circuit 105-2 is shown as including five dies 115, an integrated circuit 105 may include a different number of dies 115 (e.g., at least two dies 115). A first die 115-1 (sometimes called a bottom die or a base die) may be disposed on the substrate 110, a second die 115-2 may be disposed on the first die 115-1, and so on. Although FIG. 1 shows the dies 115 stacked in a straight stack (e.g., with aligned die edges), in some implementations, the dies 115 may be stacked in a different arrangement, such as a shingle stack (e.g., with die edges that are not aligned, which provides space for wire bonding near the edges of the dies 115).

The apparatus 100 may include a casing 120 that protects internal components of the apparatus 100 (e.g., the integrated circuits 105) from damage and environmental elements (e.g., particles) that can lead to malfunction of the apparatus 100. The casing 120 may be a mold compound, a plastic (e.g., an epoxy plastic), a ceramic, or another type of material depending on the functional requirements for the apparatus 100.

In some implementations, the apparatus 100 may be included as part of a higher level system (e.g., a computer, a mobile phone, a network device, an SSD, a vehicle, or an Internet of Things device), such as by electrically connecting the apparatus 100 to a circuit board 125, such as a printed circuit board. For example, the substrate 110 may be disposed on the circuit board 125 such that electrical contacts 130 (e.g., bond pads) of the substrate 110 are electrically connected to electrical contacts 135 (e.g., bond pads) of the circuit board 125.

In some implementations, the substrate 110 may be mounted on the circuit board 125 using solder balls 140 (e.g., arranged in a ball grid array), which may be melted to form a physical and electrical connection between the substrate 110 and the circuit board 125. Additionally, or alternatively, the substrate 110 may be mounted on and/or electrically connected to the circuit board 125 using another type of connector, such as pins or leads. Similarly, an integrated circuit 105 may include electrical pads (e.g., bond pads) that are electrically connected to corresponding electrical pads (e.g., bond pads) of the substrate 110 using electrical bonding, such as wire bonding, bump bonding, or the like. The interconnections between an integrated circuit 105, the substrate 110, and the circuit board 125 enable the integrated circuit 105 to receive and transmit signals to other components of the apparatus 100 and/or the higher level system. Furthermore, the interconnections between the integrated circuit 105, the substrate 110, and the circuit board 125 enable the integrated circuit 105 circuit to be electrically coupled with the substrate 110 and the circuit board 125.

As shown in the detailed view in the lower left of FIG. 1, the substrate 110 may include multiple layers that are conjoined. In other words, the substrate 110 may be a multi-layer circuit board. Additionally, or alternatively and as shown in the detailed view in the lower right of FIG. 1, the circuit board 125 may include multiple layers that are conjoined. In other words, the circuit board 125 may also be a multi-layer circuit board. In some implementations, the substrate 110 and/or the circuit board 125 are PCBs.

As shown in the detailed views, a layer stack included in the substrate 110 and/or the circuit board 125 may include one or more conductive layers 145. A conductive layer 145 may be an electrical conductor and may comprise, consist of, or consist essentially of conductive material. The conductive material may comprise, consist of, or consist essentially of an aluminum material, a copper material, a nickel; material, a tin material, a gold material, a silver material, or another suitable conductive material, among other examples. Furthermore, a conductive layer 145 may include patterned, electrical traces to transmit signaling to and/or from the integrated circuits 105-1 and 105-2.

Additionally, a layer stack included in the substrate 110 and/or the circuit board 125 may include one or more dielectric layers 150. A dielectric layer 150 may each be electrical insulator and may comprise, consist of, or consist essentially of insulative material. The insulative material may comprise, consist of, or consist essentially of a fiberglass epoxy material, a polyimide material, a polytetrafluoroethylene material, a ceramic material, or another suitable insulative material, among other examples. The dielectric layers 150 may be interspersed with the conductive layers 145 and provide electrical isolation between the conductive layers 145 to enable functionality of the apparatus 100.

The substrate 110 and/or the circuit board 125 may further include one or more stimulus-responsive strain layers 155. A stimulus-responsive strain layer 155 may actively respond to external stimuli by undergoing reversible changes in dimensions and/or properties. Furthermore, a stimulus-responsive strain layer 155 may, in response to a stimulus, exert a mechanical stress and/or strain across the substrate 110 and/or the circuit board 125.

In some implementations, a stimulus-responsive strain layer 155 may comprise, consist of, or consist essentially of piezoelectric material. The piezoelectric electric material comprise, consist of, or consist essentially of a quartz material such as alpha-quartz, beta-quartz, fused quartz, synthetic quartz, ceramic quartz, amorphous quartz, or another suitable quartz. Additionally, or alternatively, the piezoelectric material comprise, consist of, or consist essentially of a potassium niobate material, a lead zirconate titanate material, a barium titanate material, or another suitable piezoelectric material, among other examples. The piezoelectric material may undergo deformation when subjected to an external stimulus that is an electrical field.

Alternatively, and in some implementations, a stimulus-responsive strain layer 155 may comprise, consist of, or consist essentially of a thermal expansion material. The thermal expansion material comprise, consist of, or consist essentially of a kovar material, a super invar material, a silicon material, an aluminum silicon alloy material, a carbon fiber reinforced polymer material, a glass ceramic material, or another suitable thermal expansion material.

In some implementations, an effective coefficient of thermal expansion (e.g., in parts per million per ° Celsius) of a stimulus-responsive strain layer 155 may be different than effective coefficient of thermal expansion of a combination the conductive layers 145 and the dielectric layers 150. The thermal expansion material may undergo deformation when subjected to an external stimulus that is a thermal load.

A material of the stimulus-responsive strain layers 155 may be different than a material of the conductive layers 145 and also be different than a material of the dielectric layers 150. Furthermore, although materials of the stimulus-responsive strain layers 155 are herein described the context of a piezoelectric material or a thermal expansion material, other materials that are responsive to other external stimuli are within the scope of the present disclosure.

Based on a particular application, a multi-layer circuit board may include different configurations, quantities, and/or arrangements of conductive layers 145, dielectric layers 150, and/or stimulus-responsive strain layers 155. For example, as and as shown in FIG. 1, the substrate 110 may include the conductive layers 145-1 and 145-2 (e.g., two conductive layers), the dielectric layers 150-1 through 150-4 (e.g., four dielectric layers), and the stimulus-responsive strain layer 155-1 (e.g., a single stimulus-responsive strain layer), where the stimulus-responsive strain layer 155-1 is symmetrically located relative to a central axis 165-1 of the substrate 110 (e.g., symmetrically located relative to a central axis of a multi-layer structure). Further, the stimulus-responsive strain layer 155-1 is conjoined with the dielectric layers 150-2 and 150-3 (e.g., the stimulus-responsive strain layer 155-1 is between the dielectric layers 150-2 and 150-3).

In contrast, the circuit board 125 may include the conductive layers 145-3 and 145-4 (e.g., two conductive layers), the dielectric layers 150-5 through 150-7 (e.g., three dielectric layers), and the stimulus-responsive strain layers 155-2 and 155-3 (e.g., two stimulus-responsive strain layers), where the stimulus-responsive strain layers 155-2 and 155-3 are asymmetrically located relative to the central axis 165-2 of the circuit board 125 (e.g., asymmetrically located relative to a central axis of a multi-layer structure). The stimulus-responsive strain layer 155-2 is conjoined with the conductive layer 145-3 and the dielectric layer 150-6 (e.g., the stimulus-responsive strain layer 155-2 is between the conductive layer 145-3 and the dielectric layer 150-6). Furthermore, the stimulus-responsive strain layer 155-3 is conjoined with the conductive layer 145-4 and the dielectric layer 150-7 (e.g., the stimulus-responsive strain layer 155-3 is sandwiched between the conductive layer 145-4 and the dielectric layer 150-7).

In some implementations, a stimulus generator (e.g., a voltage source, or a thermal source) may apply stimuli equally across the stimulus-responsive strain layers 155 (e.g., the stimulus-responsive strain layers 155 of the substrate 110 and/or the circuit board 125 may be symmetrically loaded with stimuli of a same magnitude). Alternatively, and in some implementations, the stimulus generator may apply stimuli unequally across the stimulus-responsive strain layers 155 (e.g., the stimulus-responsive strain layers 155 of the substrate 110 and/or the circuit board 125 may be asymmetrically loaded with stimuli of different magnitudes for greater control over warpage of the substrate 110 and/or the circuit board 125).

As indicated above, FIG. 1 is provided as an example. Other examples may differ from what is described with regard to FIG. 1 and include different quantities and/or arrangements of the conductive layers 145, different quantities and/or arrangements of the dielectric layers 150, and/or include different quantities and/or arrangements of the stimulus-responsive strain layers 155.

In some implementations, a structure may pass through one or more of the stimulus-responsive strain layers 155. For example, and as shown in FIG. 1, a vertical interconnect access structure (via) 170 may pass through the stimulus-responsive strain layer 155-2 (and the dielectric layer 150-6) to electrically couple the conductive layers 145-3 and 145-4. The via 170 may include a conductive material that may comprise, consist of, or consist essentially of an aluminum material, a copper material, a nickel; material, a tin material, a gold material, a silver material, or another suitable conductive material, among other examples.

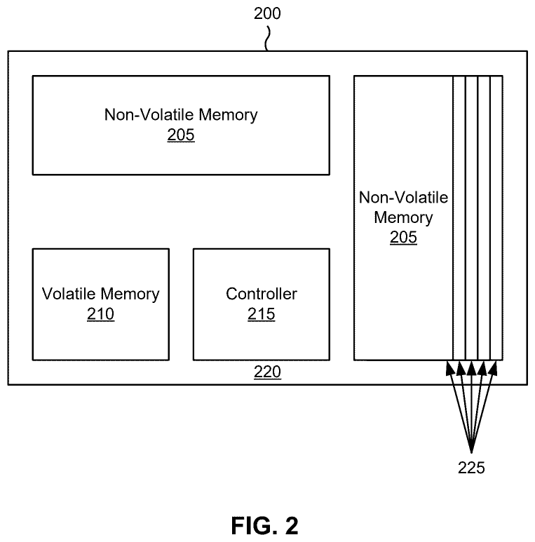

FIG. 2 is a diagram of an example memory device 200 that may be manufactured using techniques described herein. The memory device 200 is an example of the apparatus 100 described above in connection with FIG. 1. The memory device 200 may be any electronic device configured to store data in memory. In some implementations, the memory device 200 may be an electronic device configured to store data persistently in non-volatile memory 205. For example, the memory device 200 may be a hard drive, an SSD, a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device.

As shown, the memory device 200 may include non-volatile memory 205, volatile memory 210, and a controller 215. The components of the memory device 200 may be mounted on or otherwise disposed on a substrate 220. The substrate 220 may correspond to the substrate 110 or the circuit board 125 of FIG. 1. Additionally, or alternatively, the substrate 220 may include one or more layers described connection with the substrate 110 and/or the circuit board 125 of FIG. 1 (e.g., the conductive layers 145, the dielectric layers 150, and/or the stimulus-responsive strain layers 155).

In some implementations, the non-volatile memory 205 includes a single die. Additionally, or alternatively, the non-volatile memory 205 may include multiple dies, such as stacked semiconductor dies 225 (e.g., in a straight stack, a shingle stack, or another type of stack), as described above in connection with FIG. 1.

The non-volatile memory 205 may be configured to maintain stored data after the memory device 200 is powered off. For example, the non-volatile memory 205 may include NAND memory or NOR memory. The volatile memory 210 may require power to maintain stored data and may lose stored data after the memory device 200 is powered off. For example, the volatile memory 210 may include one or more latches and/or RAM, such as DRAM and/or SRAM. As an example, the volatile memory 210 may cache data read from or to be written to non-volatile memory 205, and/or may cache instructions to be executed by the controller 215.

The controller 215 may be any device configured to communicate with the non-volatile memory 205, the volatile memory 210, and a host device (e.g., via a host interface of the memory device 200). For example, the controller 215 may include a memory controller, a system controller, an ASIC, an FPGA, a processor, a microcontroller, and/or one or more processing components. In some implementations, the memory device 200 may be included in a system that includes the host device. The host device may include one or more processors configured to execute instructions and store data in the non-volatile memory 205.

The controller 215 may be configured to control operations of the memory device 200, such as by executing one or more instructions (sometimes called commands). For example, the memory device 200 may store one or more instructions as firmware, and the controller 215 may execute those one or more instructions. Additionally, or alternatively, the controller 215 may receive one or more instructions from a host device via a host interface, and may execute those one or more instructions. For example, the controller 215 may transmit signals to and/or receive signals from the non-volatile memory 205 and/or the volatile memory 210 based on the one or more instructions, such as to transfer data to (e.g., write or program), to transfer data from (e.g., read), and/or to erase all or a portion of the non-volatile memory 205 (e.g., one or more memory cells, pages, sub-blocks, blocks, or planes of the non-volatile memory 205).

As indicated above, FIG. 2 is provided as an example. Other examples may differ from what is described with regard to FIG. 2. The number and arrangement of components shown in FIG. 2 are provided as an example. In practice, there may be additional components, fewer components, different components, or differently arranged components than those shown in FIG. 2.

As described in connection with FIG. 1 and FIG. 2, and in some implementations, an apparatus (e.g., the apparatus 100 or the memory device 200) includes a dielectric layer (e.g., at least one of the dielectric layers 150) that includes a first material that is an insulative material. The apparatus includes a conductive layer (e.g., at least one of the conductive layers 145) that includes a second material that is a conductive material. The apparatus includes a stimulus-responsive strain layer (e.g., at least one of the stimulus-responsive strain layers 155) that includes a third material that deforms in response to an applied stimulus, wherein the third material is different than the first material, wherein the third material is different than the second material, and wherein the dielectric layer, the conductive layer, and the stimulus-responsive strain layer are conjoined in a layer stack (e.g., conjoined as part of the substrate 110, the circuit board 125, or the substrate 220).

Additionally, or alternatively an in some implementations, a semiconductor device assembly (e.g., the apparatus 100 or the memory device 200) includes an integrated circuit die (e.g., at least one of the integrated circuit dies 115) and a substrate (e.g., the substrate 110 or the circuit board 125) electrically coupled with the integrated circuit die. The substrate includes a dielectric layer (e.g., at least one of the dielectric layers 150), a conductive layer (e.g., at least one of the conductive layers 145), and a piezoelectric layer (e.g., at least one of the stimulus-responsive strain layers 155).

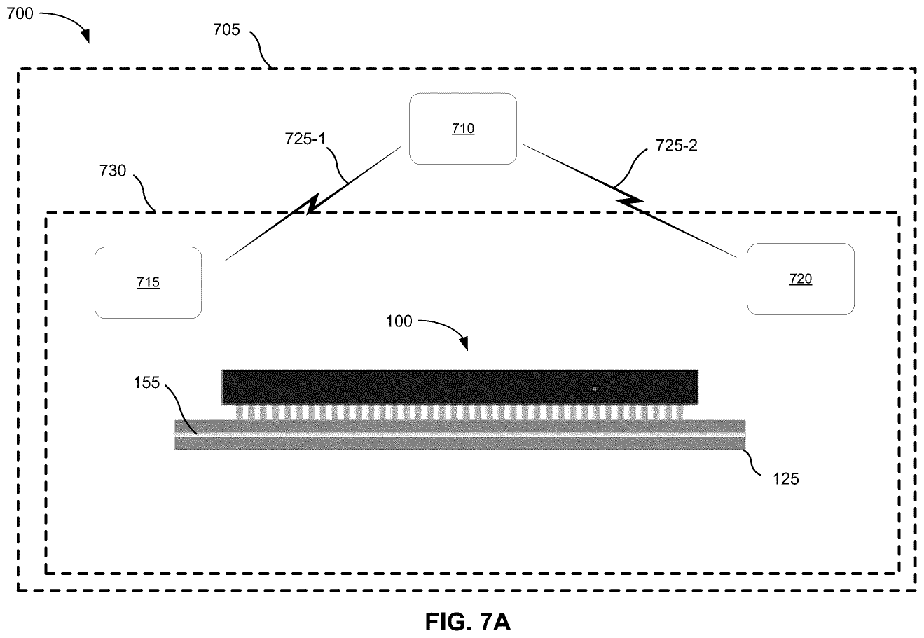

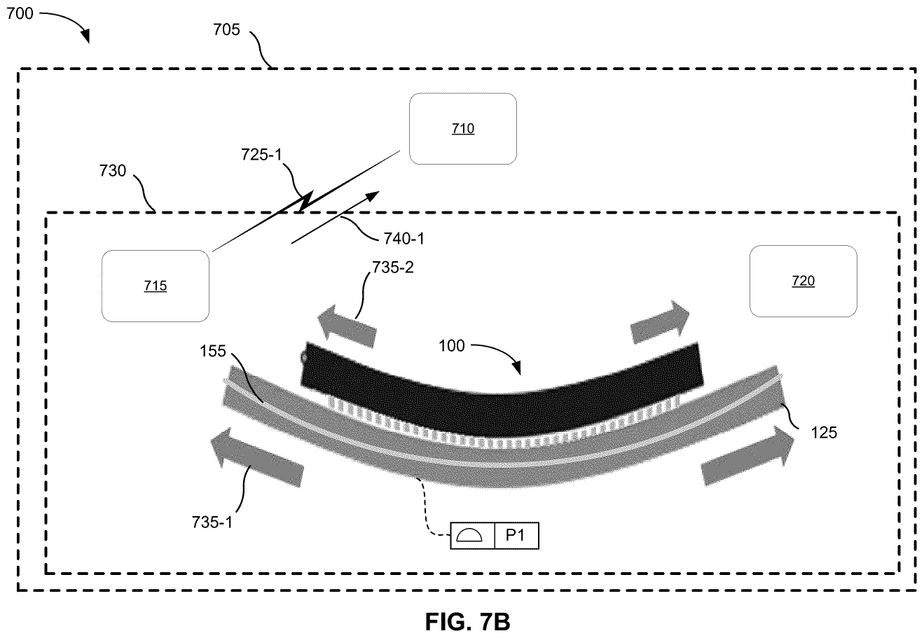

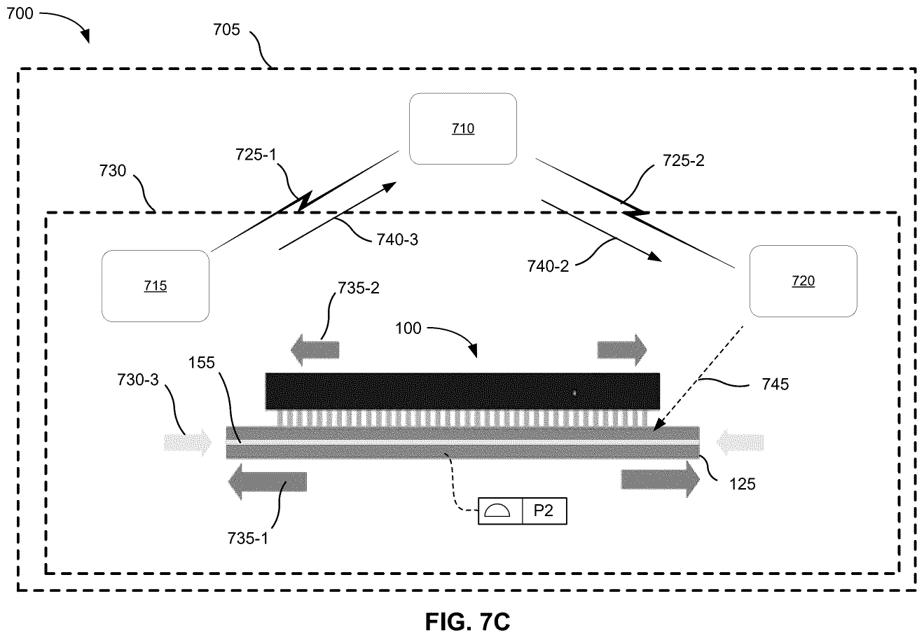

As described in greater detail in connection with FIGS. 7A-7C, the implementations may reduce quality and reliability defects during manufacturing of an assembly that includes a multi-layer circuit board including the stimulus-responsive strain layer. The implementations may also improve a performance of an end-use system that uses the assembly. By improving the quality and reliability of the assembly, as well as improving the performance of the end-use system, an amount of resources used to support a market consuming a product including the assembly (e.g., raw materials, manufacturing tools, labor, and/or computing resources) is reduced.

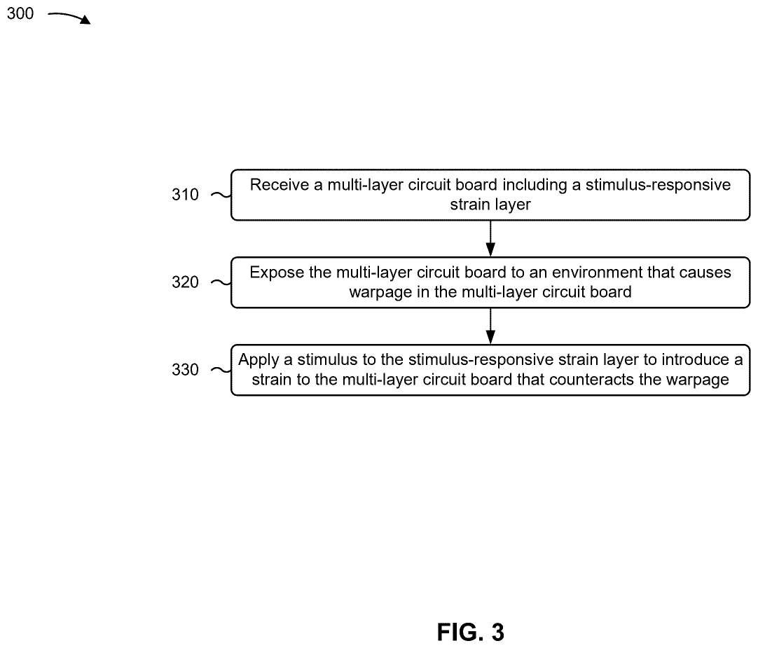

FIG. 3 is a flowchart of an example method 300 associated with a multi-layer circuit board (e.g., the substrate 110, the circuit board 125, or the substrate 220) including a stimulus-responsive strain layer (e.g., the stimulus-responsive strain layer 155) described herein. In some implementations, and as described in greater detail in connection with FIG. 7A through FIG. 7C, an automated system (e.g., a manufacturing tool such as a reflow oven or an end-use application such as a server) may perform or may be configured to perform the method 300. In some implementations, another device or a group of devices separate from or including the automated system may perform or may be configured to perform the method 300. Thus, means for performing the method 300 may include the automated system and/or one or more components of the automated system. Additionally, or alternatively, a non-transitory computer-readable medium may store one or more instructions that, when executed by a controller of the automated system, cause the automated system to perform the method 300.

As shown in FIG. 3, the method 300 may include receiving a multi-layer circuit board (e.g., the substrate 110, the circuit board 125, or the substrate 220) including a stimulus-responsive strain layer (e.g., the stimulus-responsive strain layer 155) (block 310). As further shown in FIG. 3, the method 300 may include exposing the multi-layer circuit board to an environment that causes warpage in the multi-layer circuit board (block 320). As further shown in FIG. 3, the method 300 may include applying a stimulus to the stimulus-responsive strain layer to introduce a strain to the multi-layer circuit board that counteracts the warpage (block 330).

The method 300 may include additional aspects, such as any single aspect or any combination of aspects described below and/or described in connection with one or more other methods or operations described elsewhere herein.

In a first aspect, exposing the multi-layer circuit board to the environment includes exposing the multi-layer circuit board to a reflow operation at an elevated temperature, wherein the reflow operation reflows a solder used to join a semiconductor package to the multi-layer circuit board.

In a second aspect, alone or in combination with the first aspect, exposing the multi-layer circuit board to the environment includes inserting the multi-layer circuit board into a connector that causes the warpage.

In a third aspect, alone or in combination with one or more of the first and second aspects, applying the stimulus to the stimulus-responsive strain layer includes receiving information from a sensor, and adjusting a setting that controls a magnitude of the stimulus based on the information.

In a fourth aspect, alone or in combination with one or more of the first through third aspects, receiving the information includes receiving information corresponding to a temperature condition from a thermal sensor, receiving information corresponding to a strain condition from a strain sensor, or receiving information corresponding to a deformation condition from a laser sensor.

In a fifth aspect, alone or in combination with one or more of the first through fourth aspects, adjusting the setting includes adjusting a setting controlling a magnitude of a voltage, or adjusting a setting controlling a magnitude of a thermal load.

In a sixth aspect, alone or in combination with one or more of the first through fifth aspects, the stimulus-responsive strain layer is a first stimulus-responsive strain layer, the stimulus is a first stimulus, and the method 300 includes applying a second stimulus to a second stimulus-responsive strain layer included in the multi-layer circuit board, where magnitudes of the first stimulus and the second stimulus are different.

Although FIG. 3 shows example blocks of a method 300, in some implementations, the method 300 may include additional blocks, fewer blocks, different blocks, or differently arranged blocks than those depicted in FIG. 3. Additionally, or alternatively, two or more of the blocks of the method 300 may be performed in parallel. The method 300 is an example of one method that may be performed by one or more devices described herein. These one or more devices may perform or may be configured to perform one or more other methods based on operations described herein.

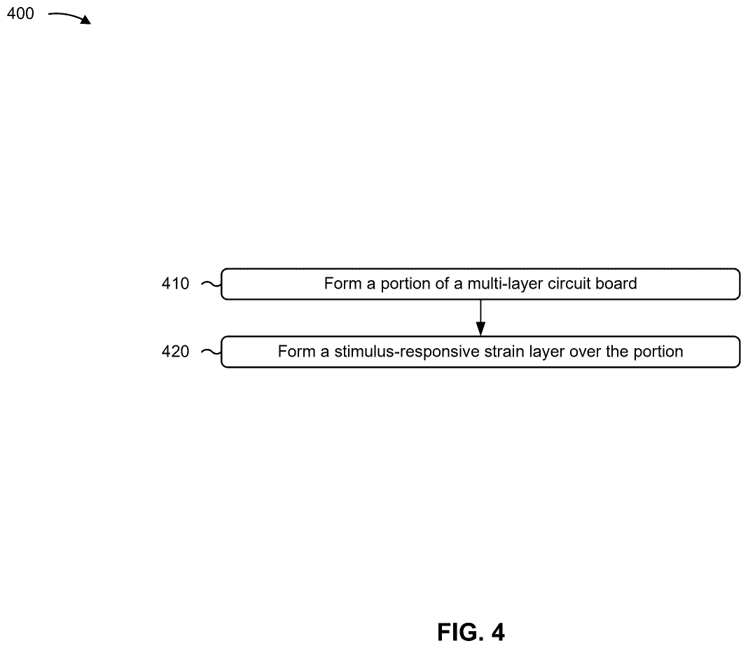

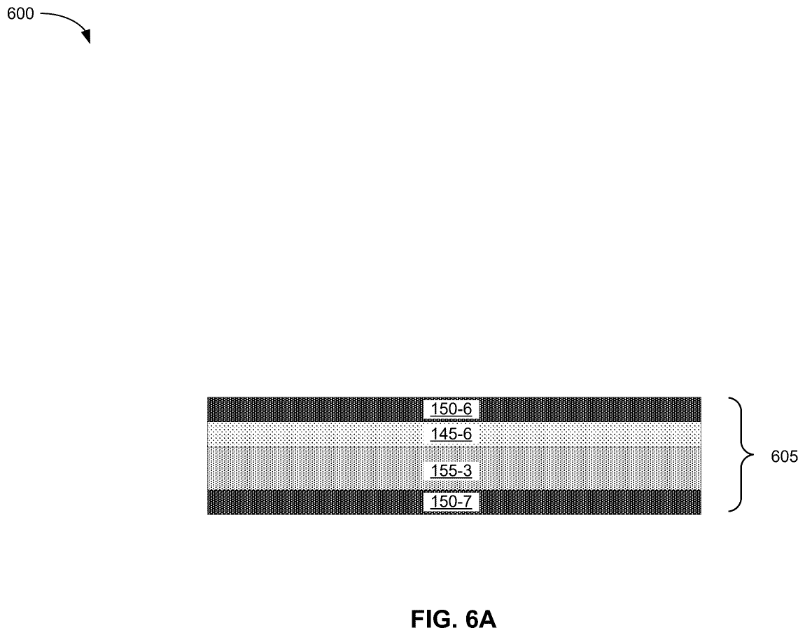

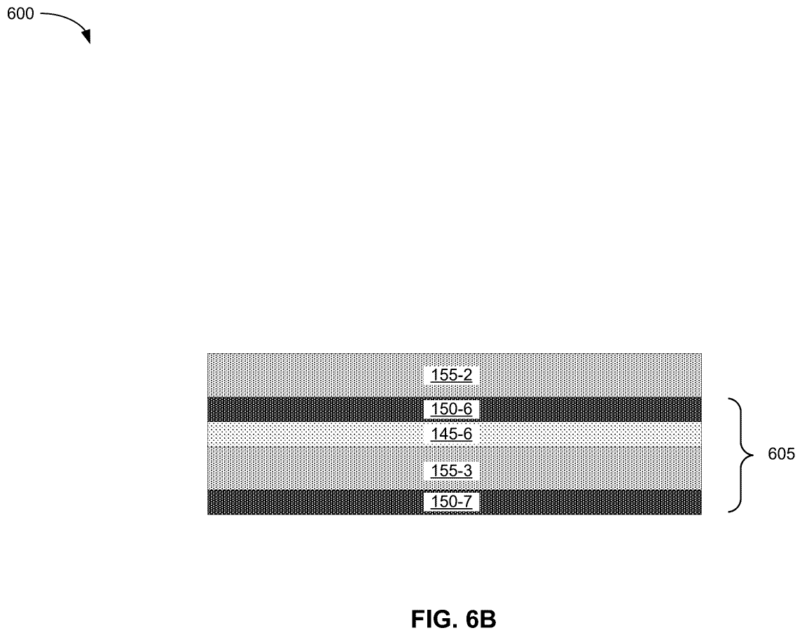

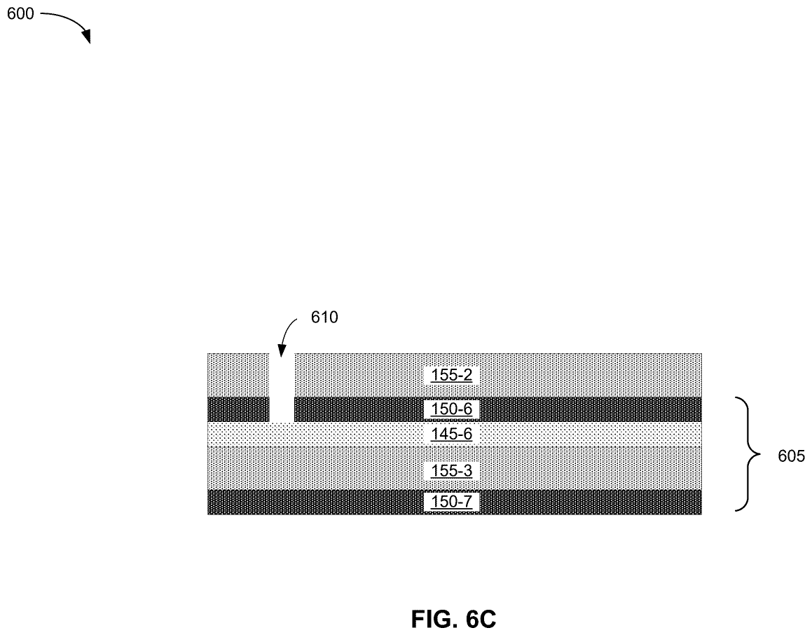

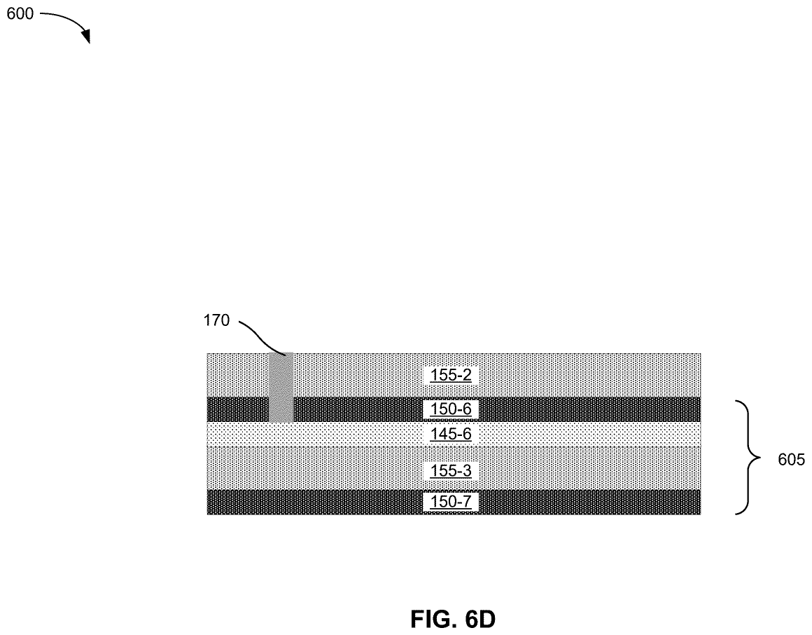

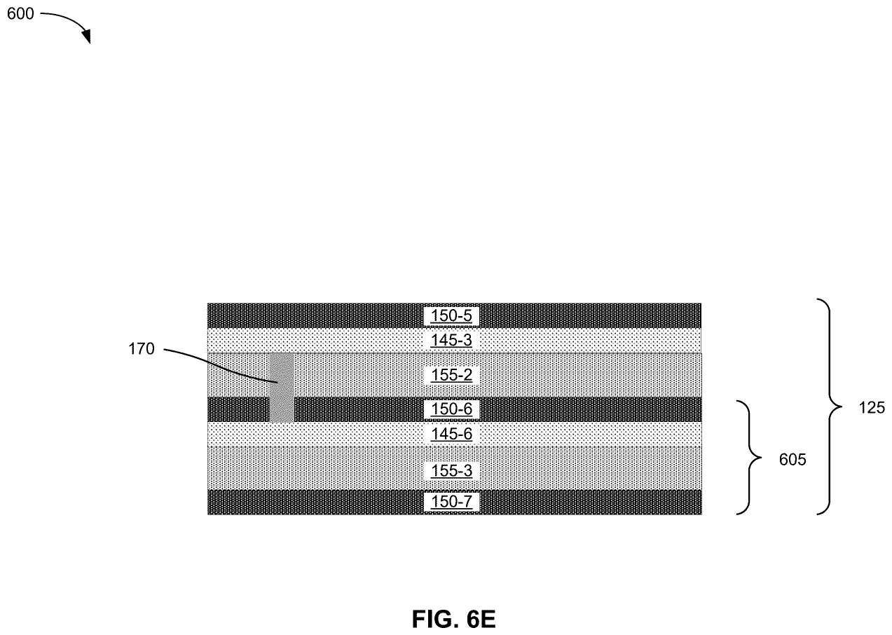

FIG. 4 is a flowchart of an example method 400 of forming an integrated assembly or memory device (e.g., the apparatus 100 or the memory device 200) having a multi-layer circuit board (e.g., the substrate 110, the circuit board 125, or the substrate 220) including a stimulus-responsive strain layer (e.g., the stimulus-responsive strain layer 155) described herein. In some implementations, and as described in greater detail in connection with FIG. 6A through FIG. 6E, one or more process blocks of FIG. 4 may be performed by various semiconductor manufacturing equipment.

As shown in FIG. 4, the method 400 may include forming a portion of a multi-layer circuit board (block 410). As further shown in FIG. 4, the method 400 may include forming a stimulus-responsive strain layer (e.g., the stimulus-responsive strain layer 155) over the portion (block 420).

The method 400 may include additional aspects, such as any single aspect or any combination of aspects described below and/or in connection with one or more other methods described elsewhere herein.

In a first aspect, forming the portion of the multi-layer circuit board includes forming a dielectric layer (e.g., the dielectric layer 150), and wherein forming the stimulus-responsive strain layer over the portion includes laminating the stimulus-responsive strain layer directly on the dielectric layer.

In a second aspect, alone or in combination with the first aspect, forming the portion of the multi-layer circuit board includes forming a conductive layer (e.g., the conductive layer 145) including a pattern of electrical traces, and wherein forming the stimulus-responsive strain layer over the portion includes laminating the stimulus-responsive strain layer directly on the conductive layer including the pattern of electrical traces.

In a third aspect, alone or in combination with one or more of the first and second aspects, forming the portion of the multi-layer circuit board includes forming a dielectric layer (e.g., the dielectric layer 150), and wherein forming the stimulus-responsive strain layer over the portion includes depositing the stimulus-responsive strain layer directly on the dielectric layer using a chemical vapor deposition technique, a physical vapor deposition technique, or a crystal growth technique.

In a fourth aspect, alone or in combination with one or more of the first through third aspects, forming the portion of the multi-layer circuit board includes forming a conductive layer (e.g., the conductive layer 145) including a pattern of electrical traces, and wherein forming the stimulus-responsive strain layer over the portion includes depositing the stimulus-responsive strain layer directly on the conductive layer using a chemical vapor deposition technique, a physical vapor deposition technique, or a crystal growth technique.

In a fifth aspect, alone or in combination with one or more of the first through fourth aspects, the method 400 includes forming a vertical interconnect access structure (e.g., the via 170) through the stimulus-responsive strain layer.

Although FIG. 4 shows example blocks of the method 400, in some implementations, the method 400 may include additional blocks, fewer blocks, different blocks, or differently arranged blocks than those depicted in FIG. 4. In some implementations, the method 400 may include forming the multi-layer circuit board, an integrated assembly that includes the multi-layer circuit board, any part described herein of the multi-layer circuit board, and/or any part described herein of an integrated assembly that includes the multi-layer circuit board. For example, the method 400 may include forming one or more parts of the apparatus 100 or the memory device 200.

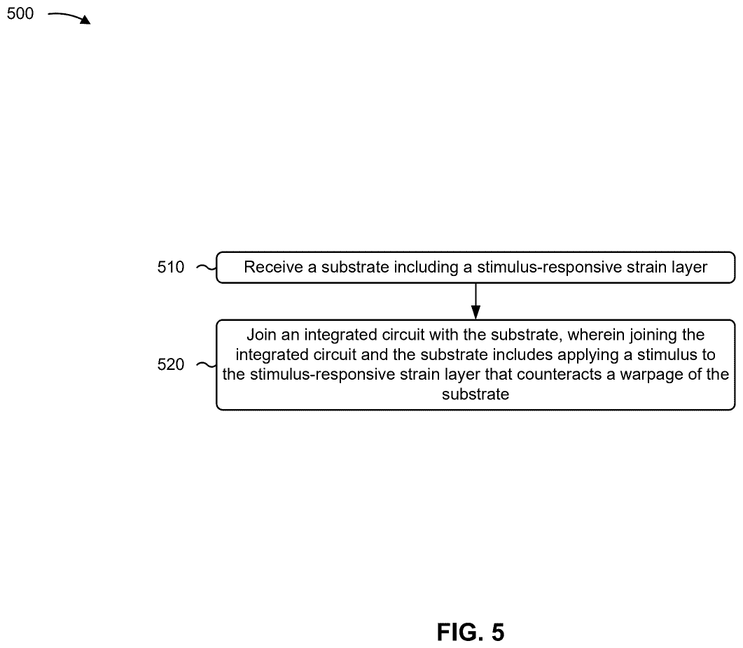

FIG. 5 is a flowchart of an example method 500 of forming an integrated assembly or memory device (e.g., the apparatus 100 or the memory device 200) having a multi-layer circuit board (e.g., the substrate 110, the circuit board 125, or the substrate 220) including a stimulus-responsive strain layer (e.g., the stimulus-responsive strain layer 155) described herein. In some implementations, and as described in greater detail in connection with FIGS. 6A through 6E, one or more process blocks of FIG. 5 may be performed by various semiconductor manufacturing equipment.

As shown in FIG. 5, the method 500 may include receiving a substrate (e.g., the substrate 110, the circuit board 125, or the substrate 220) including a stimulus-responsive strain layer (e.g., the stimulus-responsive strain layer 155) (block 510). As further shown in FIG. 5, the method 500 may include joining an integrated circuit (e.g., the integrated circuit 105) with the substrate, wherein joining the integrated circuit and the substrate includes applying a stimulus to the stimulus-responsive strain layer that counteracts a warpage of the substrate (block 520).

The method 500 may include additional aspects, such as any single aspect or any combination of aspects described below and/or in connection with one or more other methods described elsewhere herein.

Although FIG. 5 shows example blocks of the method 500, in some implementations, the method 500 may include additional blocks, fewer blocks, different blocks, or differently arranged blocks than those depicted in FIG. 5. In some implementations, the method 500 may include forming the multi-layer circuit board, an integrated assembly that includes the multi-layer circuit board, any part described herein of the multi-layer circuit board, and/or any part described herein of an integrated assembly that includes the multi-layer circuit board. For example, the method 500 may include forming one or more parts of the apparatus 100 or the memory device 200.

FIGS. 6A through 6E are diagrammatic views showing formation of a multi-layer circuit board (e.g., the circuit board 125) having a stimulus-responsive strain layer (e.g., the stimulus-responsive strain layer 155) at example process stages of an example process of forming the multi-layer circuit board. In some implementations, the example process described below in connection with FIGS. 6A through 6E may correspond to the method 300, the method 400, the method 500, one or more blocks of the method 300, one or more blocks of the method 400, and/or one or more blocks of the method 500. However, the process described below is an example, and other example processes may be used to form the multi-layer circuit board, an integrated assembly that includes the multi-layer circuit board, and/or one or more parts of the multi-layer circuit board and/or the integrated assembly.

As shown in FIG. 6A, the process 600 may include receiving a portion 605 of a multi-layer circuit board. As shown in FIG. 6A, the portion 605 (e.g., a portion of the circuit board 125 in a partially-formed state) includes the conductive layer 145-6, the dielectric layers 150-6 and 150-7, and the stimulus-responsive strain layer 155-3. In some implementations, receiving the portion 605 may include receiving the portion in a panel format, including multiples of the multi-layer circuit board.

As shown in FIG. 6B, the process 600 may include forming the stimulus-responsive strain layer 155-2 over and/or on the portion 605 (e.g., on the dielectric layer 150-6). In some implementations, forming the stimulus-responsive strain layer 155-2 over and/or on the portion 605 includes using a lamination tool to laminate the stimulus responsive strain layer 155-2 directly on the portion 605. Alternatively, and in some implementations, forming the stimulus-responsive strain layer 155-2 over and/or on the portion 605 includes using a deposition tool to deposit the stimulus-responsive strain layer 155-2 directly on the portion 605 using a physical vapor deposition (PVD) technique, a chemical vapor deposition (CVD) technique, a crystal growth technique, or another suitable deposition technique, among other examples.

As shown in FIG. 6C, the process 600 may include forming a cavity 610 through the stimulus-responsive strain layer 155-2 and the dielectric layer 150-6 to expose the conductive layer 145-6. Forming the cavity 610 may include using a set of lithography tools to form a patterned mask over the stimulus-responsive strain layer 155-2 and using an etch tool to form the cavity 610 using a wet etch technique, a dry etch technique, or another suitable etch technique, among other examples.

As shown in FIG. 6D, the process 600 may include forming the via 170 (e.g., a “buried” via) in the cavity 610. Forming the via 170 may include a using a deposition tool to deposit a conductive material in the cavity using a PVD technique, a CVD technique, an electroplating technique, or another suitable deposition technique, among other examples.

As shown in FIG. 6E, the process 600 may include forming the conductive layer 145-3 over and/or on the stimulus-responsive strain layer 155-2. Forming the conductive layer 145-3 may include using a lamination tool to laminate a layer of a conductive material directly on the stimulus responsive-strain layer 155-2 and using a set of lithography tools to form a pattern of electrical traces from the layer of the conductive material. Furthermore, and as shown in FIG. 6E, the process 600 may include forming the dielectric layer 150-5 over and/or on the conductive layer 145-3. Forming the dielectric layer 150-5 may include using a lamination tool to laminate the dielectric layer 150-5 directly on the conductive layer 145-3.

As indicated above, the process steps described in connection with FIGS. 6A through 6E are provided as examples. Other examples may differ from what is described with respect to FIGS. 6A through 6E. Furthermore, the structure shown in FIG. 6E may be equivalent to the circuit board 125 described herein.

FIG. 7A through FIG. 7C are diagrammatic views of an example series of operations 700 related to a multi-layer circuit board (e.g., the circuit board 125) including a stimulus-responsive strain layer (e.g., the stimulus-responsive strain layer 155). In some implementations, the operations 700 are be performed by a semiconductor manufacturing tool used to manufacture an integrated assembly (e.g., the apparatus 100 or the memory device 200), such as a reflow tool that is part of a surface mount (SMT) assembly line. In some implementations, the operations 700 are performed by and end-use system that includes the multi-layer circuit board, such as a computing system including a memory module that uses the multi-layer circuit board or a server including a motherboard that uses the multi-layer circuit board.

FIGS. 7A through 7C include an automated system 705 that includes a controller 710, a sensor 715, and a stimulus generator 720. As an example, the automated system 705 may be a semiconductor manufacturing tool such as a reflow oven of an SMT assembly line that is used to reflow a solder as part of joining the apparatus 100 with the circuit board 125. Alternatively, the automated system 705 may be an end-use system, such as a computing system (e.g., a server). In such a case, the circuit board 125 may electrically couple with a socket or an edge connector in the computing system.

The controller 710 may include a processor, memory, and/or other integrated circuitry. The sensor 715 may include a strain sensor (e.g., a strain gauge sensor, a fiber Bragg grating sensor, a piezoelectric sensor, a bandgap shift sensor) that is affixed to the circuit board 125, a thermal sensor, or a laser sensor, among other examples.

In some implementations, the stimulus generator 720 may be a voltage source that is electrically coupled with the stimulus-responsive strain layer 155. Alternatively, the stimulus generator may be a thermal source (e.g., a thermal plate) that is mechanically coupled with the stimulus-responsive strain layer 155 (e.g., mechanically coupled to enable thermal conduction between the thermal source and the stimulus-responsive strain layer 155).

The controller 710 may communicate with the sensor 715 and/or the stimulus generator 720 using one or more communication links 725. The one or more communication links 725 may include or more wireless-communication links, one or more wired-communication links, or a combination of one or more wireless-communication links and one or more wired-communication links, among other examples. In some implementations, the controller is separate from the automated system 705.

The system 705 includes an environment 730. In some implementations, the environment 730 corresponds to a chamber of a reflow oven. Alternatively, and in some implementations, the environment 730 corresponds to a rack and/or a socket associated with a computing system.

As shown in FIG. 7A, the series of operations 700 may include receiving the circuit board 125 including the stimulus-responsive strain layer 155. As shown in FIG. 7A, the apparatus 100 is connected with the circuit board 125 (e.g., connected with pads of the circuit board 125).

As shown in FIG. 7B, the operations 700 may include introducing a stress 735-1 (e.g., a stress in megapascals (MPa)) to the circuit board 125 and/or a stress 735-2 to the apparatus 100. In some implementations, the stress 735-1 and the stress 735-2 have different magnitudes and/or directions, causing strains in the circuit board 125 that cause a curvature P1 (e.g., a warpage) of the circuit board 125. In some implementations, the warpage may induce shear and/or bending stresses to interconnects between the apparatus 100 and the circuit board 125. Additionally, or alternatively and in some implementations, the warpage may induce shear and/or bending stresses to interconnects between a die of the apparatus 100 and a substrate of the apparatus 100.

Introducing the stress 735-1 and/or the stress 735-2 may include exposing the circuit board 125 and/or the apparatus 100 to an elevated temperature in the environment 730. As an example, the elevated temperature may be in a reflow oven used to form solder joints between the apparatus 100 and the circuit board 125. As another example, the elevated temperature may be in a computing system having insufficient cooling. In such a case, the stresses 735-1 and 735-2 may be thermal stresses induced by the environment 730.

Alternatively, and in some implementations, introducing the stress 735-1 and the stress 735-2 may include exposing the circuit board 125 and/or the apparatus 100 to forces in the environment 730 (e.g., the circuit board 125 may be inserted into a socket in the environment 730). In such a case, the stresses 735-1 and 735-2 may be bending stresses induced by the environment 730.

As further shown in FIG. 7B, the series of operations 700 may include the sensor 715 detecting the curvature P1 and transmitting information 740-1 (e.g., information related to a magnitude of the curvature P1) to the controller 710 using the communication link 725-1. The controller 710 may receive the information 740-1 and determine that the curvature P1 fails to satisfy a threshold related to acceptable deformation of the circuit board 125.

As shown in FIG. 7C, the series of operations 700 may include the controller 710 transmitting information 740-2 to the stimulus generator 720 using the communication link 725-2. In some implementations, the information 740-2 corresponds to a command that activates the stimulus generator 720 to initiate a stimulus 745 (e.g., an electrical load or a thermal load) upon the stimulus-responsive strain layer 155. Additionally, or alternatively and in some implementations, the information 740-2 corresponds to a command that adjusts setting of the stimulus generator 720 to control a magnitude of the stimulus 745 (e.g., a magnitude of a voltage or a magnitude of a temperature).

In response to receiving the stimulus 745, the stimulus-responsive strain layer 155 may change in shape, dimension, and/or form to introduce the stress 730-3 to circuit board 125. The stress 730-3 may induce a strain that counteract the warpage of the circuit board 125 such that the curvature P2 of the circuit board satisfies the threshold related to acceptable deformation of the circuit board 125. In some implementations, a quality of solder joints formed during a reflow operation that uses the interconnects to join the apparatus 100 and the circuit board 125 may be improved. Additionally, or alternatively and in some implementations, a reliability of the solder joints in an end use environment that subjects the solder joints to thermal cycling (e.g., in the computing system with insufficient cooling) may be improved.

As indicated above, FIGS. 7A through 7C are provided as an example. Other examples may differ from what is described with regard to FIGS. 7A through 7C.

In some implementations, an apparatus includes a dielectric layer, comprising: a first material that is an insulative material; a conductive layer, comprising: a second material that is a conductive material; and a stimulus-responsive strain layer, comprising: a third material that deforms in response to an applied stimulus, wherein the third material is different than the first material, wherein the third material is different than the second material, and wherein the dielectric layer, the conductive layer, and the stimulus-responsive strain layer are conjoined in a layer stack.

In some implementations, a semiconductor device assembly includes an integrated circuit die; and a substrate electrically coupled with the integrated circuit die, comprising: a dielectric layer; a conductive layer; and a piezoelectric layer.

In some implementations, a method includes receiving a multi-layer circuit board including a stimulus-responsive strain layer; exposing the multi-layer circuit board to an environment that causes warpage in the multi-layer circuit board; and applying a stimulus to the stimulus-responsive strain layer to introduce a strain to the multi-layer circuit board that counteracts the warpage.

In some implementations, a method includes forming a portion of a multi-layer circuit board; and forming a stimulus-responsive strain layer over the portion.

In some implementations, a method includes receiving a substrate including a stimulus-responsive strain layer; and joining an integrated circuit with the substrate, wherein joining the integrated circuit and the substrate includes applying a stimulus to the stimulus-responsive strain layer that counteracts a warpage of the substrate.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. An apparatus, comprising:
a dielectric layer, comprising:
a first material that is an insulative material;
a conductive layer, comprising:
a second material that is a conductive material; and
a stimulus-responsive strain layer, comprising:
a third material that deforms in response to an applied stimulus,
wherein the third material is different than the first material,
wherein the third material is different than the second material, and
wherein the dielectric layer, the conductive layer, and the stimulus-responsive strain layer are conjoined in a layer stack.

2. The apparatus of claim 1, wherein the applied stimulus is an electrical load, and wherein the third material comprises:
a material that deforms in response to the electrical load.

3. The apparatus of claim 2, wherein the material that deforms in response to the electrical load comprises:
a quartz material,
a potassium niobate material,
a lead zirconate titanate material, or
a barium titanate material.

4. The apparatus of claim 1, wherein the stimulus-responsive strain layer is symmetrically located relative to a central axis of a multi-layer structure including the dielectric layer, the conductive layer, and the stimulus-responsive strain layer.

5. The apparatus of claim 1, wherein the stimulus-responsive strain layer is asymmetrically located relative to a central axis of a multi-layer structure including the dielectric layer, the conductive layer, and the stimulus-responsive strain layer.

6. A semiconductor device assembly, comprising:
an integrated circuit die; and
a substrate electrically coupled with the integrated circuit die, comprising:
a dielectric layer;
a conductive layer; and
a piezoelectric layer.

7. The semiconductor device assembly of claim 6, wherein the substrate is a printed circuit board of a memory module.

8. The semiconductor device assembly of claim 6, wherein the integrated circuit die comprises:
dynamic random access memory integrated circuitry, or
NAND memory integrated circuitry.

9. The semiconductor device assembly of claim 6, wherein the substrate is an interposer of a semiconductor package that includes the integrated circuit die.

10. The semiconductor device assembly of claim 6, wherein the dielectric layer comprises:
a ceramic material.

11. The semiconductor device assembly of claim 6, wherein the substrate is a motherboard of a computing system.

12. The semiconductor device assembly of claim 6, further comprising:
a strain sensor affixed to the substrate.

13. A method, comprising:
receiving a multi-layer circuit board including a stimulus-responsive strain layer;
exposing the multi-layer circuit board to an environment that causes warpage in the multi-layer circuit board; and
applying a stimulus to the stimulus-responsive strain layer to introduce a strain to the multi-layer circuit board that counteracts the warpage.

14. The method of claim 13, wherein exposing the multi-layer circuit board to the environment includes:
exposing the multi-layer circuit board to a reflow operation at an elevated temperature,
wherein the reflow operation reflows a solder used to join a semiconductor package to the multi-layer circuit board.

15. The method of claim 13, wherein exposing the multi-layer circuit board to the environment includes:
inserting the multi-layer circuit board into a connector that causes the warpage.

16. The method of claim 13, wherein applying the stimulus to the stimulus-responsive strain layer includes:
receiving information from a sensor; and
adjusting a setting that controls a magnitude of the stimulus based on the information.

17. The method of claim 16, wherein receiving the information includes:
receiving information corresponding to a temperature condition from a thermal sensor,
receiving information corresponding to a strain condition from a strain sensor, or
receiving information corresponding to a deformation condition from a laser sensor.

18. The method of claim 16, wherein adjusting the setting includes:
adjusting a setting controlling a magnitude of a voltage, or
adjusting a setting controlling a magnitude of a thermal load.

19. The method of claim 13, wherein the stimulus-responsive strain layer is a first stimulus-responsive strain layer, the stimulus is a first stimulus, and further including:
applying a second stimulus to a second stimulus-responsive strain layer included in the multi-layer circuit board,
wherein magnitudes of the first stimulus and the second stimulus are different.

20. A method, comprising:
forming a portion of a multi-layer circuit board; and
forming a stimulus-responsive strain layer over the portion.

21. The method of claim 20, wherein forming the portion of the multi-layer circuit board includes forming a dielectric layer, and
wherein forming the stimulus-responsive strain layer over the portion includes:
laminating the stimulus-responsive strain layer directly on the dielectric layer.

22. The method of claim 20, wherein forming the portion of the multi-layer circuit board includes forming a conductive layer including a pattern of electrical traces, and
wherein forming the stimulus-responsive strain layer over the portion includes:
laminating the stimulus-responsive strain layer directly on the conductive layer including the pattern of electrical traces.

23. The method of claim 20, wherein forming the portion of the multi-layer circuit board includes forming a dielectric layer, and
wherein forming the stimulus-responsive strain layer over the portion includes:
depositing the stimulus-responsive strain layer directly on the dielectric layer using a chemical vapor deposition technique, a physical vapor deposition technique, or a crystal growth technique.

24. The method of claim 20, wherein forming the portion of the multi-layer circuit board includes forming a conductive layer including a pattern of electrical traces, and
wherein forming the stimulus-responsive strain layer over the portion includes:
depositing the stimulus-responsive strain layer directly on the conductive layer using a chemical vapor deposition technique, a physical vapor deposition technique, or a crystal growth technique.

25. The method of claim 20, further comprising:
forming a vertical interconnect access structure through the stimulus-responsive strain layer.
